(19) United States
(12) Patent Application Publication
(10) Pub. No.: US 2009/0224833 A1
(43) Pub. Date: Sep. 10, 2009

(54) AMPLIFIER

(76) Inventor: John David Rhodes, Menston (GB)

Correspondence Address: HOWARD & HOWARD ATTORNEYS PLLC, 450 West Fourth Street, Royal Oak, MI, 48067, US

(21) Appl. No.: 12/094,023

(22) PCT Filed: Nov. 16, 2005
(86) PCT No.: PCT/GB05/04401

§ 371 Date: Oct. 9, 2008

(51) Int. Cl. H03F 3/16

(52) U.S. Cl. 330/277

(57) ABSTRACT

An amplifier comprising a digitally pre-distorted Laterally Diffused Metal Oxide Semiconductor (LDMOS) transistor and a biassing circuit is described. The gate bias voltage defines an operating point of the LDMOS transistor such that the quiescent drain current of the LDMOS transistor is substantially invariant when an input signal of varying power is applied. The quiescent drain current is the drain current of the at least one LDMOS transistor when the input signal is instantaneously removed. Such an amplifier has reduced intermodulation products in its output for input signals of varying power levels. The intermodulation products are reduced for input signals of less than maximum power as well as maximum power.

The present application relates to amplifiers. It is particularly applied to amplifiers for radio frequency signals, including amplifiers for use in mobile telephone base stations.

Mobile telephone communication systems are known. In general, the systems operate by providing a network of base stations with each base station covering a certain geographical area, or cell. The mobile telephone communicates with the base station which then provides onward links to other base stations, or other communications networks. Recently, so-called 3G telephones have been implemented. These systems can achieve high data rate mobile communications. Mobile telephones are required to operate within strict frequency bands. It is important that the signals transmitted from the base stations are within the correct frequency band so as not to interfere with signals of other operators.

The design of amplifiers for use with 3G mobile telephone base stations is complex. The amplifier must operate as linearly as possible with the applied signal to reduce intermodulation components of the signal introduced out of the required band as a result of non-linearities. It must operate at high output powers, for example 50 to 100 W up to as much as 500 W in some cases.

In a conventional application of an amplifier, the power transistors (the transistors that amplify the signal) are biased so that its analogue performance is optimised with respect to linearity of operation and amplifier efficiency. However, the linearity of such an amplifier is still not good enough to reduce out of band interference from intermodulation components sufficiently for 3G mobile telephone applications.

In order to improve the linearity, it is known to apply digital pre-distortion to the input signals of the amplifier. The pre-distortion uses a mathematical model of the amplifier to adjust the input signal to compensate for the non-linearities in the amplifier. The mathematical model may include memory-less components, which are based on the instantaneous value of the input signal only, and memory components, which take into account previous values of the input signal.

Techniques for digital pre-distortion can give very good results with signals having a constant power level. For example, in the Freescale Technology Forum held in Orlando in 2005, it was advised that digital pre-distortion techniques were sufficiently good that design of an amplifier could concentrate on improving the efficiency of amplification, a digital pre-distortion stage would suppress intermodulation products in the output signal.

However, the performance of a digitally pre-distorted amplifier is still not ideal for 3G mobile telephone base stations. For example, the High Speed Downlink Packet Access (HSDPA) protocol for 3G uses signals having changing power levels that vary over timescales of approximately two-thirds of a millisecond. While digital pre-distortion works well with signals having a constant power level, intermodulation products are increased when it is used with signals of varying power levels. It has been proposed to update the pre-distortion algorithm over similar time periods that the signal changes but the inevitable delay in calculating and updating the model gives poor performance for rapidly varying signals, such as those in HSDPA.

It is an object of the present invention to provide an amplifier with reduced intermodulation products in the output signal independent of the dynamics of the input signal, i.e. an amplifier with an improved linear output characteristics for input signals of varying power levels.

Accordingly the present invention provides an amplifier comprising a digital pre-distorter system; at least one Laterally Diffused Metal Oxide Semiconductor (LDMOS) transistor and a biassing circuit that defines an operating point of the at least one LDMOS transistor such that the quiescent drain current in the at least one LDMOS transistor remains substantially invariant to changes in the power level of a signal to be amplified.

The quiescent drain current is defined as the instantaneous drain current in the LDMOS transistor if the applied signal is instantaneously removed.

The performance of the amplifier can be improved by biassing an LDMOS transistor used with a digital pre-distorter in this way. Surprisingly, the operating point does not correspond to the optimum operating point for operation without pre-distortion. Previously, it was thought that the best performance was obtained by biassing the amplifier for optimum performance without a digital pre-distorter. Alternatively, it was proposed at the Freescale Technology Forum 2005 that selecting a more efficient operating point without a digital pre-distorter gives better performance. However, an amplifier operated at either of these operating points does not have good performance when used with signals of varying input power. In particular, the intermodulation products are only effectively reduced for maximum signal power and not other, lower, signal powers.

An amplifier biassed according to the present invention demonstrates improved linearity of the output signal for dynamically varying signals, with reduced intermodulation products causing out-of band interference achieved at different power levels. Unlike previously proposed biassing points, the biassing point of the present invention surprisingly demonstrates improved linearity over several power levels of input signal. At all previously proposed biassing points, the linearity was strongly dependent on the power level of the input signal, and there has been nothing to suggest that this dependency on power level was due to the particular biassing point selected for the transistor.

According to a first aspect of the present invention, there is provided an amplifier for amplifying a radio frequency input signal comprising:

at least one LDMOS transistor for amplifying the radio frequency input signal;

a biassing circuit for defining the gate bias point of the at least one LDMOS transistor;

a digital pre-distorter for pre-distorting the radio frequency signal before it is supplied to the LDMOS transistor, wherein the digital pre-distorter is determined for a signal of maximum input power at the gate bias point defined by the biassing circuit; and

wherein the biassing circuit comprises components selected such that the quiescent drain current of the at least one LDMOS transistor is substantially invariant when an input signal of varying power is applied, wherein the quiescent drain current is the drain current of the at least one LDMOS transistor when the input signal is instantaneously removed.

“Substantially invariant” is used to refer to the fact that the quiescent drain current responds substantially independently of the previous value of the signal, i.e. when the power level of a signal changes, there is no significant time for the quiescent drain current to reach its steady state level at the new power level.

In a further aspect, there is provided an amplifier for amplifying a radio frequency input signal comprising:

at least one LDMOS transistor for amplifying the radio frequency signal;

a biassing circuit for defining the gate bias point of the at least one LDMOS transistor;

a digital pre-distorter for pre-distorting the radio frequency signal before it is supplied to the at least one LDMOS transistor, wherein the digital pre-distorter is determined for a signal of maximum input power at the gate bias point defined by the biassing circuit; and

wherein the biassing circuit comprises components selected such that the decay effects on the quiescent drain current of the at least one LDMOS transistor when an input signal of varying power is applied are minimised, wherein the quiescent drain current is the drain current of the at least one LDMOS transistor when the input signal is instantaneously removed.

“Decay effects” is used to refer to the presence of a finite rate of change of the quiescent drain current in response to an instantaneous variation in the power of the input signal, so that the quiescent drain current does not change instantaneously.

In a further aspect, there is provided an amplifier for amplifying a radio frequency input signal comprising:

at least one LDMOS transistor for amplifying the radio frequency signal;

a biassing circuit for defining the gate bias point of the at least one LDMOS transistor;

a digital pre-distorter for pre-distorting the radio frequency signal before it is supplied to the LDMOS transistor, wherein the digital pre-distorter is determined for a signal of maximum input power at the gate bias point defined by the biassing circuit; and

wherein the biassing circuit comprises components selected such that 50 μs, preferably 10 μs from the input signal being removed, the quiescent drain current of the at least one LDMOS transistor is within 5%, preferably 1%, of its value before the input signal was applied, and wherein the quiescent drain current is the drain current of the at least one LDMOS transistor when the input signal is instantaneously removed.

The person skilled in the art can easily determine whether a transistor is operating at the biassing point of the above aspects by measuring the quiescent drain current and its response to a radio frequency signal of varying signal power. For example, the drain current could be measured by connecting a resistor in series with the drain and measuring the voltage across the resistor at the instant the full power signal is removed.

In the above-described aspects, the present invention reduces the intermodulation products in the amplified signal when a signal of less than maximum power is amplified. The biassing point of the present invention gives only slightly less efficiency for a maximum power input signal as an amplifier biassed towards Class B. Efficiency is reduced with lower power input signals but this is normally not important and is more than compensated by the reduced intermodulation products in the amplified signal.

The digital pre-distorter uses coefficients determined at the biassing point of the invention for an input signal of maximum power. Surprisingly, this pre-distorter is effective across several power levels of input signal, not just one as was previously the case.

According to a further aspect of the present invention, there is provided an amplifier for amplifying a radio frequency input signal comprising:

at least one LDMOS transistor for amplifying the radio frequency signal;

a biassing circuit for defining the gate bias voltage of the at least one LDMOS transistor;

a digital pre-distorter for pre-distorting the radio frequency signal before it is supplied to the LDMOS transistor, wherein the digital pre-distorter is determined for a signal of maximum input power at the gate bias voltage; and

wherein the gate bias voltage is selected such that intermodulation products in the output of the amplifier are minimised for a maximum power signal and for a signal at 6 dB less than maximum power.

This uses the surprising result that a particular biassing point can result in improved linearity with the digital pre-distorter across a range of power levels of input signal. This is contrary to previously proposed biassing points, chosen to correspond to good performance without a pre-distorter, in which the linearity was strongly dependent on the power of the input signal.

According to a further aspect of the present invention, there is provided a base station for a mobile telephone system, the base station comprising an amplifier according to one of the above described first or second aspects of the invention. The amplifier of the first or second aspects is particularly well suited for use in mobile telephone base station, particularly those for use with 3G systems and HSDPA.

According to further aspect of the present invention, there is provided a method of amplifying a radio frequency input signal comprising:

providing an amplification circuit comprising at least one LDMOS transistor;

biassing the LDMOS transistor at a gate bias point wherein the quiescent drain current is substantially invariant when an input signal of varying power is applied, wherein the quiescent drain current is the drain current of the at least one LDMOS transistor when the input signal is instantaneously removed; and

digitally pre-distorting the signal before it is supplied to the amplification circuit, using a mathematical model determined for a signal of maximum input power at the gate bias point.

According to further aspect of the present invention, there is provided a method of amplifying a radio frequency input signal comprising:

providing an amplification circuit comprising at least one LDMOS transistor;

biassing the LDMOS transistor at a gate bias point such that the decay effects on the quiescent drain current of the at least one LDMOS transistor when an input signal of varying power is applied are minimised, wherein the quiescent drain current is the drain current of the at least one LDMOS transistor when the input signal is instantaneously removed; and

digitally pre-distorting the signal before it is supplied to the amplification circuit, using a mathematical model determined for a signal of maximum input power at the gate bias point.

According to further aspect of the present invention, there is provided a method of amplifying a radio frequency input signal comprising:

providing an amplification circuit comprising at least one LDMOS transistor;

biassing the LDMOS transistor at a gate bias point such that 50 μs, preferably 10 μs from the input signal being removed, the quiescent drain current of the at least one LDMOS transistor is within 5%, preferably 1%, of its value before the input signal was applied, wherein the quiescent drain current is the drain current of the at least one LDMOS transistor when the input signal is instantaneously removed; and

digitally pre-distorting the signal before it is supplied to the amplification circuit, using a mathematical model determined for a signal of maximum input power at the gate bias point.

According to further aspect of the present invention, there is provided a method of amplifying a radio frequency input signal comprising:

providing an amplification circuit comprising at least one LDMOS transistor;

biassing the LDMOS transistor at a gate bias point such that such that intermodulation products in the output of the amplifier are minimised for a maximum power input signal and for an input signal at 6 dB less than maximum power; and

digitally pre-distorting the signal before it is supplied to the amplification circuit, using a mathematical model determined for a signal of maximum input power at the gate bias point.

As discussed above, these methods reduce the intermodulation products which are present in the amplified signal when a signal of less than maximum power is amplified.

Embodiments of the invention will now be described by way of example, with reference to the accompanying drawings, in which:

FIG. 1 is a graph of the quiescent drain current in response to a short pulse of a multi-carrier WCDMA signal in an LDMOS transistor which has been biased close to a Class B condition;

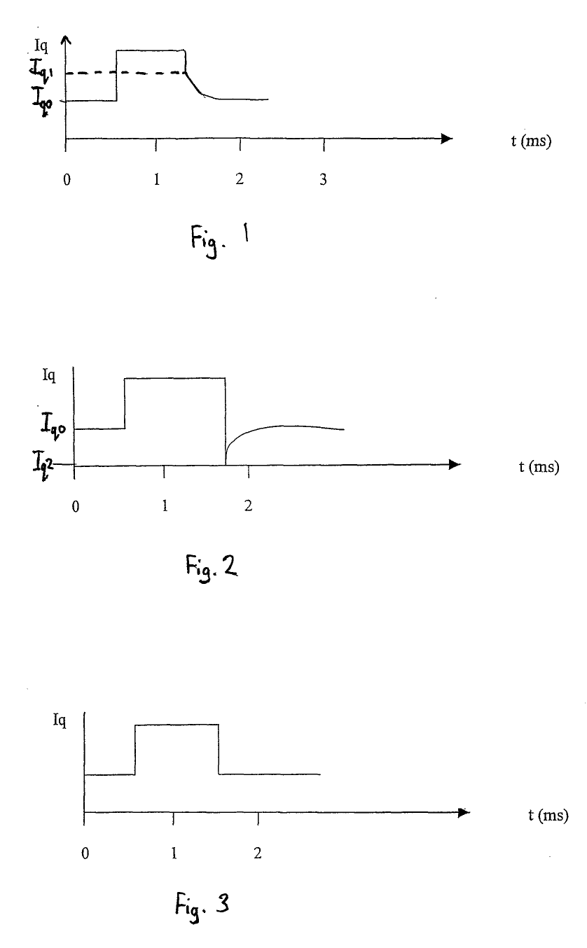

FIG. 2 is a graph of the quiescent drain current in response to a short pulse of a multi-carrier WCDMA signal in an LDMOS transistor which has been biased close to a Class A condition;

FIG. 3 is a graph of the quiescent drain current in response to a short pulse of a multi-carrier WCDMA signal in an LDMOS transistor which has been biased at the optimum point in class AB according to the present invention;

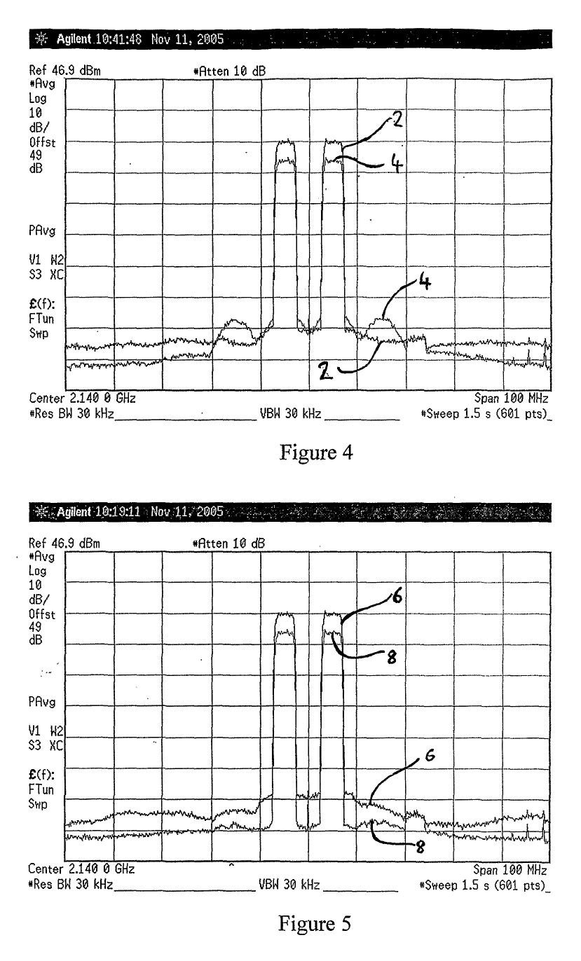

FIG. 4 is a graph of the output spectrum of a digitally pre-distorted amplifier biassed at a conventional operating point for an input signal of maximum power and an input signal reduced in power by 6 dB; and

FIG. 5 is a graph of the output spectrum of a pre-distorted amplifier biassed at an operating point according to the present invention for an input signal of maximum power and an input signal reduced in power by 6 dB.

Firstly, the concept underlying the present invention will be explained with reference to FIGS. 1 to 3. Unlike prior methods of biassing which focus on the efficiency and linearity of the amplifier, the present invention adopts a method of optimising the instantaneous quiescent drain current, I_{q}, I_{q} is defined as the instantaneous current which would exist when the input signal is instantaneously removed.

The concept underlying the present invention is based on the results of experimentation with digitally pre-distorted LDMOS amplifiers. A digitally pre-distorted amplifier is one in which the complex coefficients of the non-linear memoryless terms and several memory terms are determined for a maximum power modulated signal to minimise intermodulation products of the output signal. Such an amplifier is then linear with the pre-distorter if, and only if, the reduced intermodulation products are maintained with the application of any arbitrarily modulated signal having a maximum power level no larger than the original signal. The amplifier is assumed to be operated at the same frequency and constant background ambient temperature.

FIG. 1 is a graph of I_{q} in response to a short pulse of a multi-carrier WCDMA signal in a digitally pre-distorted LDMOS transistor which has been biassed close to a Class B condition. Before the signal is applied I_{q} has an initial value of I_{q0}. The initial application of the signal can be seen as the sharp jump in I_{q}, When the signal is removed, there is an initial sharp drop in I_{q} to a level I_{q1} between the value when the signal was applied and the original value of I_{q} before the signal was applied. I.e. I_{q} does not return instantaneously to its level before the signal was applied. The percentage deviation between this value of I_{q} and the value before the signal was applied is significant.

FIG. 1 also shows that, following the instantaneous drop in I_{q}, I_{q} decays approximately exponentially down to its value before the signal was applied. The time for I_{q} to return to its value before the signal was applied was applied is significant in the timescale of the applied signal.

FIG. 2 is a graph of I_{q} in response to a short pulse of a multi-carrier WCDMA signal in a digitally pre-distorted LDMOS transistor which has been biassed close to a Class A condition. Before the signal is applied I_{q} has an initial value of I_{q0}. The initial application of the signal can be seen as the sharp jump in I_{q}, When the signal is removed, it can be seen that I_{q} drops sharply down to a value I_{q2} below the initial value and then decays approximately exponentially up to its value before the signal was applied. I.e. I_{q} does not return instantaneously to its level before the signal was applied. The percentage deviation between this value of I_{q} and the value before the signal was applied is also significant. Once again, the time for I_{q} to return to its value before the signal was applied is significant in the timescale of the applied pulse.

The present invention aims to balance these two effects, so that when an input signal is removed, I_{q} returns substantially instantaneously to its value before the input signal was applied. The biassing condition is within Class AB and results in the I_{q} shown in the graph of FIG. 3. It can be seen that I_{q} responds quickly to the change in power of the applied signal with no noticeable decay effects visible over the timescale of the graph.

The biasing point of FIG. 3 does not correspond to the conventional operating point for good linear characteristics without pre-distortion as was previously thought to be optimal. Likewise, it does not correspond to the biassing point for improved efficiency as proposed as the Freescale Developers Forum 2005. Rather, it corresponds to increased quiescent drain current that without a digital pre-distorter would give poor intermodulation performance and reduced efficiency.

It has been found that the biassing point of the present invention has significant and surprising benefits when combined with a digital pre-distorter, particularly when used to amplify dynamic signals such as those used in HSDPA. The effect of the present invention in reducing intermodulation products when an input signal is reduced in power by 6 dB is depicted in FIGS. 4 and 5.

FIG. 4 is a graph of the output spectrum of a digitally pre-distorted amplifier using an LDMOS power transistor, where the LDMOS power transistor is biassed at a conventional point that corresponds to good performance of the LDMOS power transistor without a digital pre-distorter (in this case a quiescent drain current of 1A). Curve 2 represents the output spectrum for an input signal of maximum power. Curve 4 represents the output spectrum for an input signal reduced in power by 6 dB. It can be seen that although performance at maximum power is acceptable, when the input signal is reduced in power by 6 dB significant out-of-band intermodulation products are present.

However, when the same pre-distorted amplifier is operated at the biassing point of the present invention, the performance is improved. FIG. 5 is a graph of the output spectrum of a digitally pre-distorted amplifier biassed at an operating point according to the present invention (in this case a quiescent drain current of 2A). Curve 6 represents the output spectrum for an input signal of maximum power. Curve 8 represents the output spectrum for an input signal reduced in power by 6 dB. It can be seen that the intermodulation products are significantly reduced compared with the amplifier operating at the conventional biassing point.

Unlike previously proposed biassing points, the present invention makes use of the surprising result that the biassing point of the LDMOS power transistors can be selected so that intermodulation products in the output signal for signals of varying power levels are reduced. This has not been recognised in any of the previously proposed biassing points, in all of which the intermodulation products are strongly dependent on the power level of the applied signal.

The present invention can be used with any amplifier in which the power transistors used for amplification are LDMOS transistors. As an example, in one embodiment, the amplifier may use the MRF5S21130HR3 LDMOS transistor which is commercially available from Freescale Semiconductor. The properties of this transistor are described in the Freescale Semiconductor datasheet MRF5221130H (Rev. 2, 1/2005) which is herein incorporated by reference in its entirety.

The datasheet includes graphs of the performance of the transistor when used with 2-carrier WCDMA signals. The graphs include power gain vs. output power and third order intermodulation products vs. output power. These graphs indicate that, when optimising the biassing for intermodulation products and output power using the conventional technique of choosing a point that gives good performance without a digital pre-distorter, a quiescent current of approximately 1200 mA when no signal is applied should be used. Alternatively, if the biassing method proposed at the Freescale Developers Forum 2005 is used, the operating point will have a quiescent current lower than 1200 mA, for improved efficiency. However, when the biassing method of the present invention is used, in which the bias is selected to ensure that the instantaneous quiescent drain current has substantially no decay characteristics in response to a variation in input power, an I_{q} of approximately 2600 mA when no signal is applied is determined. Examining the performance graphs of the datasheet indicate that such an operating point should be expected to give very poor performance. However, surprisingly this is not the case.

The biassing point of the present invention is therefore against the conventional teaching of the best operating point for LDMOS transistors. Advantageously, it has been found that the efficiency of the present invention is only marginally less than a Class B condition for a maximum power WCDMA signal. The efficiency is reduced at lower signal levels, although this is compensated by the greatly reduced intermodulation products.

The present invention relates to the biassing point of an LDMOS transistor and as such may be implemented using known biassing circuits in which the values of the components are selected to give a biassing point according to the present invention. For example, the datasheet MRF5221130H (Rev. 2, 1/2005) includes an example biassing circuit that can be used in the present invention. The biassing point itself can be determined by connecting a resistor in series with the drain to measure the instantaneous quiescent current. Alternatively, the biassing point may be determined by measuring the output spectrum of a digitally pre-distorted amplifier and adjusting the biassing point such that the intermodulation characteristics are minimised for a full power signal and a signal with 6 dB less power than full power.

In another embodiment of the present invention, the amplifier may further include a circuit to compensate for changes in temperature of the transistor, due to changes in ambient temperature and/or changes due to signal heating.

In another embodiment of the present invention, the coefficients of the digital pre-distortion circuit are updated periodically to take into account longer-term changes in the characteristics of the transistor. Longer-term in this case is used to indicate changes that occur over a timescale of several seconds or more.

All the embodiments of the present invention can be used in mobile phone base stations.

1. An amplifier for amplifying a radio frequency input signal comprising:
at least one LDMOS transistor for amplifying the radio frequency input signal;
a biasing circuit for defining a gate bias point of the at least one LDMOS transistor;
a digital pre-distorter for pre-distorting the radio frequency input signal before the input signal is supplied to the at least one LDMOS transistor, wherein the digital pre-distorter is determined for a signal of maximum input power at the gate bias point defined by the biasing circuit; and
wherein the biasing circuit comprises components selected such that a quiescent drain current of the at least one LDMOS transistor is substantially invariant when an input signal of varying power is applied, wherein the quiescent drain current is the drain current of the at least one LDMOS transistor when the radio frequency input signal is instantaneously removed.

2. An amplifier for amplifying a radio frequency input signal comprising:
at least one LDMOS transistor for amplifying the radio frequency signal;
a biasing circuit for defining a gate bias point of the at least one
a digital pre-distorter for pre-distorting the radio frequency input signal before the input signal is supplied to the at least one LDMOS transistor, wherein the digital pre-distorter is determined for a signal of maximum input power at the gate bias point defined by the biasing circuit; and
wherein the biasing circuit comprises components selected such that the decay effects on a quiescent drain current of the at least one LDMOS transistor are minimized when an input signal of varying power is applied, wherein the quiescent drain current is the drain current of the at least one LDMOS transistor when the radio frequency input signal is instantaneously removed.

3. An amplifier for amplifying a radio frequency input signal comprising:
at least one LDMOS transistor for amplifying the radio frequency input signal;
a biasing circuit for defining a gate bias point of the at least one LDMOS transistor;
a digital pre-distorter for pre-distorting the radio frequency input signal before the input signal is supplied to the at least one LDMOS transistor, wherein the digital pre-distorter is determined for a signal of maximum input power at the gate bias point defined by the biasing circuit; and
wherein the biasing circuit comprises components selected such that 50 [mu]s or less are removed from the radio frequency input signal, a quiescent drain current of the at least one LDMOS transistor is within at least 5% of an original value of the quiescent drain current before the radio frequency input signal is applied, and wherein the quiescent drain current is the drain current of the at least one LDMOS transistor when the radio frequency input signal is instantaneously removed.

4. An amplifier for amplifying a radio frequency input signal comprising:
at least one LDMOS transistor for amplifying the radio frequency input signal;
a biasing circuit for defining a gate bias voltage of the at least one LDMOS transistor;
a digital pre-distorter for pre-distorting the radio frequency input signal before the input signal is supplied to the at least one LDMOS transistor, wherein the digital pre-distorter is determined for a signal of maximum input power at a gate bias voltage; and
wherein the gate bias voltage is selected such that intermodulation products in the output of the amplifier are minimized for a maximum power signal.

5. (canceled)

6. A method of amplifying a radio frequency input signal comprising:
providing an amplification circuit comprising at least one LDMOS transistor;
biasing the at least one LDMOS transistor at a gate bias point wherein a quiescent drain current is substantially invariant when an input signal of varying power is applied, wherein the quiescent drain current is the drain current of the at least one LDMOS transistor when the input signal is instantaneously removed; and
digitally pre-distorting the input signal before the input signal is supplied to the amplification circuit, using a mathematical model determined for a signal of maximum input power at the gate bias point.

7. A method of amplifying a radio frequency input signal comprising:
providing an amplification circuit comprising at least one LDMOS transistor;
biasing the LDMOS transistor at a gate bias point such that the decay effects on a quiescent drain current of the at least one LDMOS transistor when an input signal of varying power is applied are minimized, wherein the quiescent drain current is the drain current of the at least one LDMOS transistor when the input signal is instantaneously removed; and
digitally pre-distorting the input signal before the input signal is supplied to the amplification circuit, using a mathematical model determined for a signal of maximum input power at the gate bias point.

8. A method of amplifying a radio frequency input signal comprising:
providing an amplification circuit comprising at least one LDMOS transistor;
biasing the at least one LDMOS transistor at a gate bias point such that 50 [mu]s or less is removed from the radio frequency input signal, a quiescent drain current of the at least one LDMOS transistor is within 5% of an original value of the quiescent drain current before the input signal is applied, wherein the quiescent drain current is the drain current of the at least one LDMOS transistor when the input signal is instantaneously removed; and
digitally pre-distorting the input signal before the input signal is supplied to the amplification circuit, using a mathematical model determined for a signal of maximum input power at the gate bias point.

9. A method of amplifying a radio frequency input signal comprising:
providing an amplification circuit comprising at least one LDMOS transistor;
biasing the LDMOS transistor at a gate bias point such that intermodulation products in the output of the amplifier are minimized for a maximum power input signal; and
digitally pre-distorting the input signal before the input signal is supplied to the amplification circuit, using a mathematical model determined for a signal of maximum input power at the gate bias point.

10. (canceled)

11. (canceled)

12. An amplifier as set forth in claim 3 wherein the biasing circuit comprises components selected such that 10 [mu]s or less are removed from the radio frequency input signal

13. An amplifier as set forth in claim 3 wherein the quiescent drain current of the at least one LDMOS transistor is within at least 1% of an original value of the quiescent drain current before the radio frequency input signal is applied

14. An amplifier as set forth in claim 4 wherein the gate bias voltage is selected such that intermodulation products in the output of the amplifier are minimized for a signal 6 dB less than the maximum power signal.

15. A method as set forth in claim 8 wherein the step of biasing the at least one LDMOS transistor is further defined as biasing the at least one LDMOS transistor at the gate bias point such that 10 [mu]s or less is removed from the radio frequency signal output.

16. A method as set forth in claim 8 wherein the step of biasing the at least one LDMOS transistor is further defined as biasing the at least one LDMOS transistor at the gate bias point such that the quiescent drain current of the at least one LDMOS transistor is within 1% of an original value of the quiescent drain current before the radio frequency input signal is applied.

17. A method as set forth in claim 9 wherein the step of biasing the at least one LDMOS transistor is further defined as biasing the at least one LDMOS transistor at a gate bias point such that intermodulation products in the output of the amplifier are minimized for a radio frequency input signal 6 dB less than maximum power.
